(19) United States
(12) Patent Application Publication
(10) Pub. No.: US 2008/0170110 A1
(43) Pub. Date: Jul. 17, 2008

(54) Circuit board with terminals arranged in a single row and disposed at board edges, cartridges with the circuit board, and methods for making same

(75) Inventor: Alan K. Chan, Fairport, NY (US)

Correspondence Address: FAY SHARPE LLP, 1100 SUPERIOR AVENUE, SEVENTH FLOOR, CLEVELAND, OH, 44114, US

(73) Assignee: Nu-kote International, Inc.

(21) Appl. No.: 11/800,732

(22) Filed: May 7, 2007

Related U.S. Application Data
(63) Continuation-in-part of application No. 10/990,634, filed on Nov. 17, 2004.

(51) Int. Cl. B41J 2/175; H05K 1/00; H05K 3/00

(52) U.S. Cl. 347/86; 174/250; 29/829

(57) ABSTRACT

A circuit board, a cartridge with the circuit board, and methods of manufacturing the circuit board and cartridge are provided. A circuit board has a storage device and a plurality of terminals arranged thereon along one axis thereof. A first set of the terminals are for read/write operations of the storage device to modify data contained in the storage device. A second set of the terminals are for communicating electrical power to the storage device. At least two of the second set of terminals are arranged on the circuit board at two edges thereof. The circuit board may be applied to a housing holding marking material. The method of manufacturing the circuit board includes defining first and second circuits having first and second terminals, respectively. A substrate is provided and the first and second circuits are formed on the substrate with the first and second terminals thereof being conjoined at a conjoined area. Thereafter, the substrate together with the first and second circuits are cut through the conjoined area. The cutting forms first and second circuit boards of first and second portions of the cut substrate. The first circuit board carries the first circuit with the first terminal extending to an edge of the first circuit board defined by the cutting. The second circuit board carries the second circuit with the second terminal extending to an edge of the second circuit board defined by the cutting.

### CROSS REFERENCE TO RELATED PATENTS AND APPLICATIONS

This application is a continuation-in-part of U.S. application Ser. No. 10/990,634, filed Nov. 17, 2004, entitled “INK CARTRIDGE WITH SEMICONDUCTOR STORAGE DEVICE”, commonly owned and expressly incorporated herein by reference.

### BACKGROUND

The present application relates to the art of printed circuit boards used in consumable products and, more particularly, to printed circuit boards, products carrying the circuit boards, and methods of their manufacture. The embodiments find particular application in conjunction with consumable printing products such as ink and toner cartridges and will be described with particular reference thereto. However, it is to be appreciated that the present exemplary embodiments are also amenable to other like applications and that the invention has broader use and can be applied in a wide range of consumer, industrial, and other products and devices including anywhere printed circuit boards are used or fabricated for any purpose.

In recent years, original equipment manufacturers (OEMs) have developed ink and toner cartridges which include electronic devices having memory units adapted to store data related to characteristics of the consumable products contained therein. As an example, several ink printer OEMs provide ink cartridges having memory devices which store data relating to the ink such as a date of manufacture and a quantity of ink contained within the cartridge as examples. Laser printer OEMs provide toner cartridges with memory devices holding data relating to electrical and chemical properties or characteristics of the toner contained within the cartridge bodies. The electronics on these consumable cartridges are typically carried on circuit boards which include a plurality of terminals arranged on a rigid or flexible circuit board substrate. The terminals are adapted to engage corresponding electrical contact tabs or the like extending from the target printer housing.

FIG. 1 schematically shows one such prior art printer and circuit board arrangement wherein a circuit board 1 has a first terminal row with a central ground terminal 2, a data I/O terminal 3 to a first side thereof, and a read/write signal terminal 4 to a second side thereof. A second row is located above the first terminal row and includes a power terminal 5 in its center, a clock signal terminal 6 to a first side thereof, and a chip select signal terminal 7 to a second side thereof. The associated printer device 8 is provided with a set of spaced-apart contact pins 9. Each of the contact pins 9 corresponds with one of the terminals 2-7 so that when the ink or toner cartridge is installed into a mounting portion of the printer, the terminals 2-7 come into contact with the corresponding contact pins 9 to enable power, data, etc. to be exchanged between the electronic storage device carried on the circuit board 1 and the printer 8.

However, in the past, there has been a problem with regard to electrical continuity being established between the contact pins 9 and the terminals 2-7 because of misalignment between the ink/toner cartridge and the printer. This is due in part because the terminals are provided in two separate rows on the circuit board 1. The use of two separate and distinct rows of terminals also makes the circuit board more expensive and difficult to manufacture. Other problems with this type of prior art circuit board is the arrangement of the power related terminals 5, 2 relative to the insertion direction of the board relative to the printer potentially causing a temporary shorting condition.

In order to provide an improvement over the circuit board 1 discussed above in connection with FIG. 1, a further prior art circuit board 10 as shown in FIG. 2 has been proposed. A through-hole 11 and a notch 12 are provided for assisting in alignment while positioning the circuit board 10 during installation thereof onto an ink or toner cartridge. A plurality of terminals 20-27 are provided on a front face of the circuit board wherein a substantially circular test terminal 20 is used to test a storage device on the opposite side of the board (not shown) when the circuit is shipped from the factory. The remaining terminals are arrayed in two rows including an upper row with an I/O terminal 21 for data input/output, a power supply terminal 22 for supplying power, and a chip select terminal 23 for input of a chip select signal for selectively activating the storage device. The terminals in the lower row include a ground terminal 24, a read/write control signal terminal 25, a clock terminal 26 for inputting a clock signal for use by the storage device, and a ground terminal 27.

This second prior art circuit board 10 is similar to the first prior art circuit board 1 discussed above in that it also includes two rows of spaced apart terminals. Thus, this board is expensive and difficult to manufacture and is prone to failure during use because of the persistent problem of potential misalignments between the various terminals on the circuit board and the corresponding contact pins of the associated printer. More particularly, slight misalignments between the contact pins on the printer and the terminals on the circuit device on a direction of insertion of the cartridge body into the printer can cause one or more registration errors resulting in an incomplete electrical circuit and thus, rendering the data in the memory unit to be useless.

Lastly, FIG. 3 shows yet a further prior art circuit board 30 having ground terminals 31, 37 located at two outermost edges of a single row of terminals, with the other terminals 32-36 being located further inwardly and between the ground terminals 31, 37. The ground terminals 31, 37 are spaced apart equally from a center power supply terminal 34. The remaining terminals include a read/write terminal 32, a clock signal terminal 33, an I/O signal terminal 35, and a chip select terminal 36. All of the terminals 31-37 have the same size.

Although the single row configuration shown in the prior art circuit 30 of FIG. 3 makes the circuit board easier to manufacture and has other benefits, the shape and arrangement of terminals on the circuit board makes the board prone to misalignment errors when engaged with the corresponding contact pins in the associated printer. The outer terminals 31, 37 are more prone to misalignment errors than the inner terminals 32-36 when the circuit board 30 is misaligned rotationally in the plane of the circuit board. Other problems have been encountered with this prior art circuit board such as, for example, lateral registration errors because the contacts are narrow. In order to accommodate several identically-sized contacts into a single row, each contact must be reduced in width proportionately to provide adequate separation between the contacts. The result is a narrow terminal having a reduced contact area, making it difficult to properly register with the corresponding terminals disposed in the associated printer.

U.S. Pat. No. 6,727,116 teaches a miniature semiconductor device package including outer connectors that are located along at least one peripheral edge thereof and that extend substantially across the height of the peripheral edge. Each outer connector is formed by severing a conductive via that extends substantially through a substrate blank, such as a silicon wafer, at a street located adjacent to an outer periphery of the semiconductor device of the package. Assemblies of these devices may include the packages in a stacked arrangement without height-adding connectors. However, devices taught in the '116 patent are substantially die-sized with respect to each of the X, Y, and Z axes. Thus, outer connectors as shown and described in the '116 patent have no practical purpose in the macro level of a printed circuit board as described above in connection with the prior art circuit boards and in relation to the environment and embodiments of the present application. More particularly, the present application relates to the art of printed circuit boards and to products carrying the circuit boards such as ink and toner cartridges which are selectively installed into marking devices and removed therefrom when the ink or toner marking material is spent. Thus, the circuit boards of the present application include contacts for selective electromechanical connection with associated pins of a printer as the circuit board and the printer are moved relative to each other. Only die-sized semiconductor device packages are taught in the '116 patent and, therefore, the connectors taught there are not fit for establishing selective electromechanical connection between members which are movable relative to each other during normal use thereof. The connectors of the '116 patent are adequate for connecting members which are not movable relative to each other during normal use thereof and are simply too small to be used on a macro scale as between printed circuit boards and associated printing apparatus.

U.S. Pat. No. 5,773,854 teaches a semiconductor device including a configuration having an array of logic gates electrically connected with an array of input/output (I/O) circuit devices, and also electrically connecting the array of connector pads by which electrical connection with the semiconductor device may be effected. The array of logic gates is linearly continuous and is unbounded along at least a first axis through to boundaries imposed on edges of the semiconductor wafer. The arrays of I/O circuit devices and connector pads are disposed adjacent, and in one embodiment parallel, to the array of logic gates. The integrated circuit structures are customized by cutting a selected length from a strip-like portion of the array of logic gates. Thus, one or more connector pads may lie close to a cut edge of the array of logic gates. However, the '854 patent has no practical use on a macro scale such as in connection with printed circuit boards of the type described in the present application. Rather, the '854 patent teaches components on a micro scale such as on the semiconductor wafer scale wherein relative movement between the connector pads and other associated connector members does not occur during normal use thereof.

Accordingly, there is a need in the art for a printed circuit board for use with cartridges holding consumable materials for printing and for a method of manufacturing same which is inexpensive, easy to manufacture, and provides good electrical contact between the electronics carried on the circuit board and contact pins disposed in the target printer to ensure power, control, and data signal integrity after the circuit board and contact pins are moved into relative operative alignment with each other. It follows also that there is correspondingly a need for a cartridge with such a circuit board as well as a method for manufacturing such a cartridge with the circuit board.

The embodiments of the present application include and provide terminals arranged at an edge of a substrate of a printed circuit board for establishing selective electromechanical connection between cartridge and printer devices as the devices are moved into relative operative engagement during normal use thereof.

### BRIEF DESCRIPTION

In accordance with aspects illustrated herein, there is provided a circuit board for use with a storage device for storing data relating to marking material consumed during a printing operation. The circuit board includes a plurality of terminals thereon arranged on the circuit board along one axis thereof. A first set of the plurality of terminals on the circuit board are provided for read/write operations of the storage device to modify the data relating to the marking material. A second set of the plurality of terminals on the circuit board are for communicating electrical power to the storage device. At least two of the first set of the plurality of terminals are arranged on the circuit board at two edges thereof.

In accordance with a further aspect, the plurality of terminals disposed on the circuit board are arranged in a single row with at least two of the first set of the plurality of terminals being located at the outermost ends of the single row.

In accordance with yet a further aspect, the first set of the plurality of terminals includes a data I/O terminal, a power supply terminal, a chip select signal terminal, a read/write control signal terminal, and a clock signal terminal wherein the data I/O terminal and the chip select signal terminal are located at the outermost ends of the row.

In accordance with a further aspect illustrated herein, a method of manufacturing a circuit board includes defining first and second circuits having, respectively, first and second terminals. A substrate is provided and the first and second circuits are formed on the substrate with the first and second terminals being conjoined at a conjoined area. The substrate, together with the first and second terminals, is cut through the conjoined area. The cutting forms a first circuit board from a first portion of the substrate and a second circuit board from a second portion of the substrate. The first circuit board of the first portion of the substrate carries the first circuit with the first terminal extending to an edge of the first circuit board defined by the cutting. Similarly, the second circuit board of the second portion of the substrate carrying the second circuit is formed with the second terminal extending to an edge of the circuit board defined by the cutting.

In accordance with a further aspect, the providing includes providing a rigid circuit board.

Still further, in the method, the defining of the first and second circuit boards includes defining a first circuit having a plurality of first terminals arranged in a single row and defining a second circuit having a plurality of second terminals arranged in a single row.

Still further, in accordance with another aspect, the defining includes defining first and second substantially identical circuits.

In accordance with a further aspect illustrated herein, a cartridge is provided for use with an associated marking device consuming marking material. The cartridge includes a housing defining a chamber configured to hold a quantity of an associated marking material, an outlet port for communicating the associated marking material from the chamber of the housing to the associated marking device, and a circuit board carried relative to the housing and including a storage device for storing data relating to the associated marking material consumed by the associated marking device. The circuit board includes a plurality of terminals thereon arranged on the circuit board along one axis thereof, a first set of the plurality of terminals being arranged on the circuit board for read/write operations of the storage device, a second set of the plurality of terminals being arranged on the circuit board for communicating electrical power to the storage space, and at least two of the first set of plurality of terminals being arranged on the circuit board at two edges thereof.

In accordance with yet a still further aspect, a method of manufacturing an apparatus for use with an associated marking device consuming marking materials provided. The method includes providing a circuit board, providing a cartridge, and mounting the circuit board in a position relative to the cartridge. The circuit board is provided in the method having a plurality of terminals thereon arranged on the circuit board along one axis thereof. A first set of the plurality of terminals are arranged on the circuit board and are for read/write operations of the storage device to modify the data relating to the marking material. A second set of the plurality of terminals are arranged on the circuit board for communicating electrical power to the storage device. At least two of the first set of the plurality of terminals are disposed on the circuit board at two edges thereof. The housing is provided in the method and defines a chamber configured to hold a quantity of the marking material. The cartridge includes an outlet port for communicating the marking material from the chamber of the housing to the associated marking device.

In accordance with a further aspect of the method, the step of providing the circuit board includes defining a plurality of circuits on a substrate and cutting the substrate to form a plurality of circuit boards, each having terminals extending two edges thereof.

These and other aspects and advantages of the methods and apparatus described and illustrated herein will become apparent to those of ordinary skill in the art upon a reading and understanding of the detailed description set out below.

### BRIEF DESCRIPTION OF THE DRAWINGS

FIG. 1 is an illustrative diagram of a first circuit board terminal arrangement in accordance with the prior art;

FIG. 2 is an illustrative diagram of a second circuit board terminal arrangement in accordance with the prior art;

FIG. 3 is an illustrative diagram depicting the contact pattern of a third circuit in accordance with the prior art;

FIG. 4 is an illustrative diagram of an exemplary circuit board terminal arrangement pertaining to a first embodiment;

FIG. 4A is a cross-sectional view of the circuit board shown in FIG. 4, taken along line 4A-4A;

FIGS. 5A and 5B are schematic diagrams illustrating a “2 up” form of the circuit board of FIG. 4 showing a method for fabricating the circuit board in accordance with an embodiment;

FIGS. 6A and 6B are schematic diagrams illustrating a “3 up” form of the circuit board of FIG. 4 showing a method for fabricating the circuit board in accordance with a further embodiment;

FIG. 7 is a flowchart illustrating a process flow for fabricating a circuit board for use on consumable electronic devices in accordance with an embodiment; and,

FIG. 8 is a schematic view of a printed circuit board provided in combination with an ink or toner cartridge in accordance with a further preferred embodiment.

### DETAILED DESCRIPTION

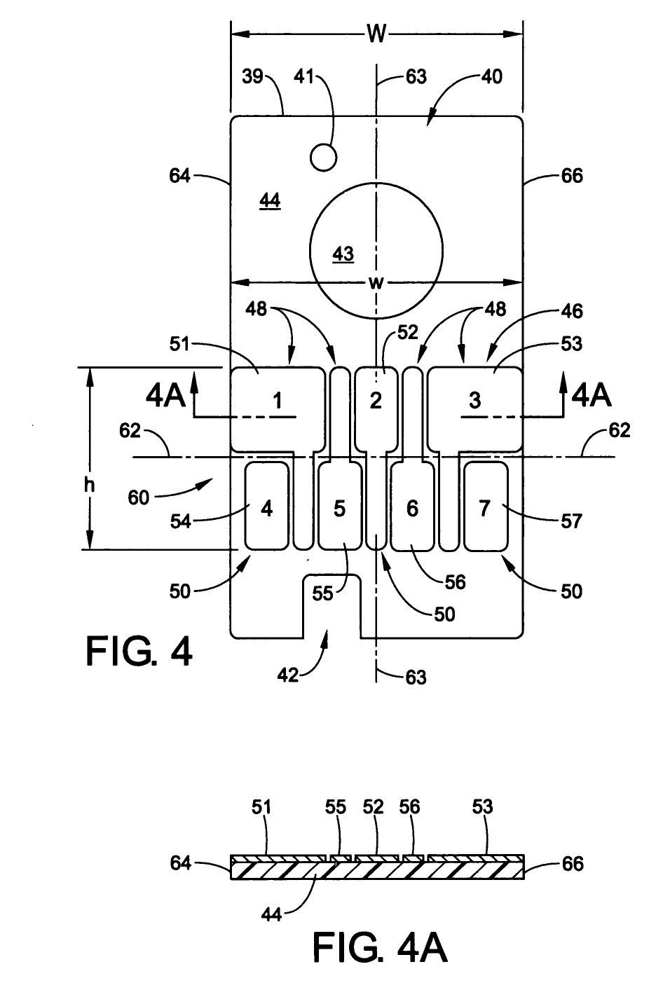

Turning now to the figures wherein the showings are for purposes of describing the preferred embodiments only and not for limiting the invention, FIG. 4 shows a printed circuit board 40 formed in accordance with a first preferred embodiment. The printed circuit board 40 is formed of a non-conductive substantially rigid substrate 41 having a generally rectangular shape. The circuit board 40 includes a through-hole 41 and a notch 42 for assisting in positioning the circuit board relative to the associated ink or toner cartridge such as in the embodiment shown in FIG. 8 during installation of the circuit board onto the cartridge. It is to be appreciated that although a rectangular shape is illustrated, the circuit board can take on any size or shape as desired. Also, although a printed circuit board (PCB) is described, the preferred embodiments include printed wiring boards (PWB) and etched wiring boards (EWB) and any other form or structure used to mechanically support and electrically connect electronic components such as integrated circuits, microcontrollers, and the like using conductive pathways, or traces, formed on a rigid or semi-rigid non-conductive substrate. The traces and other conductive portions including the contact terminals may be formed on the substrate using subtractive techniques such as silk screen printing, photoengraving, PCB milling or other means, or using additive processes such as by applying a reverse mask to the substrate and thereafter other layers of tin-lead or other surface platings. Trace layers may be formed or provided inside the PCB by forming multi-layer PCBs by bonding together separately etched thin boards.

A front face 44 of the circuit board carries a plurality of electrical contacts 46 including a first set of contacts 48 of the plurality of terminals arranged on the circuit board for executing read/write/control operations of an electronic storage device 43, and a second set of terminals 50 for communicating electrical power to the electronic storage device 43. It is to be appreciated that none of the contacts 46 are provided for or adapted to carry programming signals to or from the electronic storage device 43 for programming the device. Rather, all of the contacts 46 are for use during operation of the device and have no purpose during programming thereof.

Specifically, the plurality of electrical contacts 46 includes an input and output I/O terminal 51 for reading data from and writing data to a memory portion within the electronic storage device 43, a power supply terminal 52 for supplying power to the electronic device 43, a chip select terminal 53 for input of a chip select signal CS for selectively activating the electronic storage device 43, a ground terminal 54, a read/write terminal 55 for inputting read/write control signals W/R for the electronic storage device 43, a clock terminal 56 for inputting a clock signal CLK (a sync signal) for the storage device 43, and a ground terminal 57. The first set of terminals for providing the read/write/control operations include the I/O terminal 51, the chip select terminal 53, the read/write terminal 55, and the clock terminal 56. The second set of electrical contacts 50 for communicating electrical power to the storage device 53 includes the power supply terminal 52, and each of the ground terminals 54, 57.

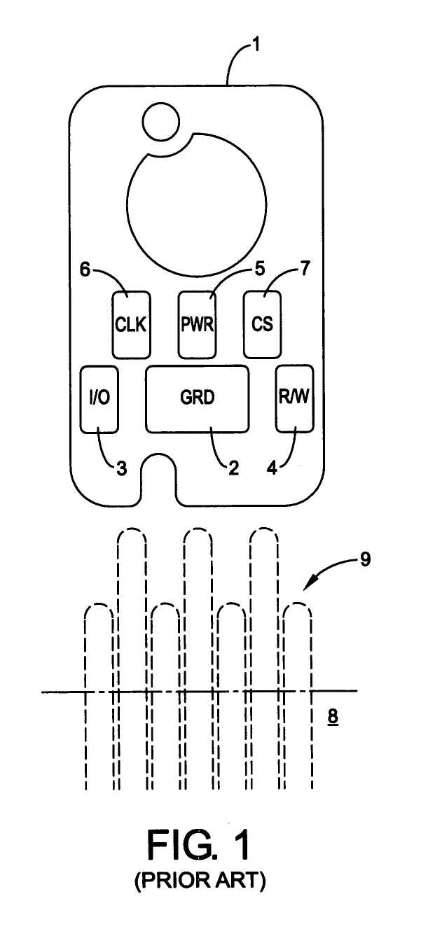

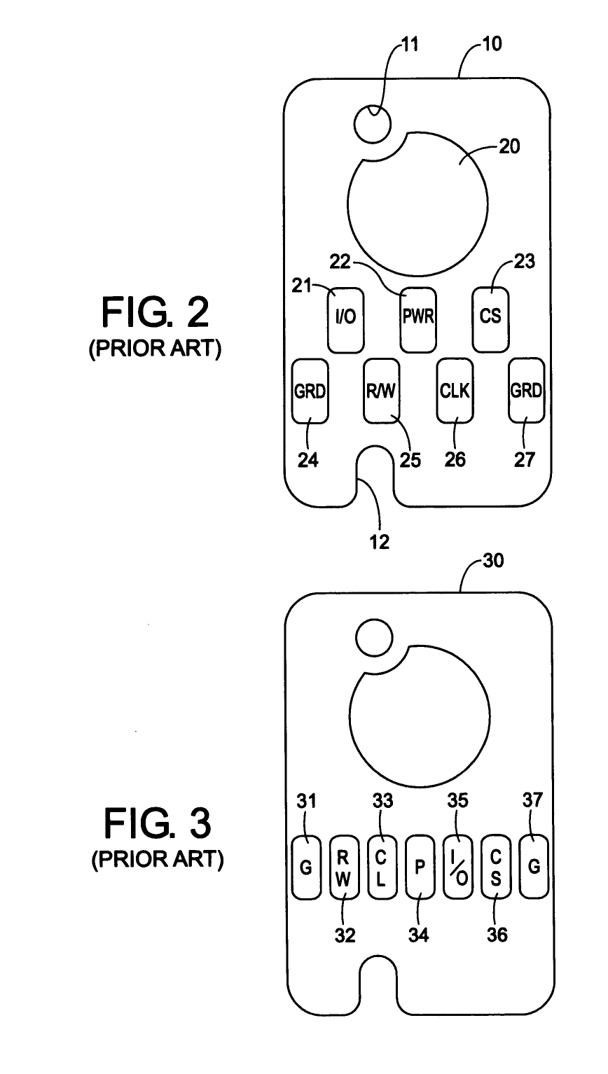

It is to be appreciated that, in accordance with the preferred embodiment, the plurality of electrical contacts 46 form a single row 60 of terminals arranged on the printed circuit board 40 along a single axis 62 as shown. The axis 62 of the single row 60 is oriented in a direction transverse to a longitudinal axis 63 of the circuit board. As illustrated in the preferred embodiment, the longitudinal axis 63 extends in a direction parallel with an insertion direction of the circuit board 40 into an associated printer device in a manner as shown schematically in FIG. 1 with regard to the prior art. More particularly, the single row 60 of electrical contact terminals 46 has a height h and a width w. As can be seen, in its preferred form, the width w of the single row 60 of the plurality of electrical contacts 46 has a dimension corresponding substantially identically with a width W of the substantially rectangular printed circuit board. Preferably, the width w of the single row corresponds identically with the width W of the printed circuit board 40. That is, the physical outermost electrical contacts 51, 53 of the single row 60 extend up to and at opposite edges 64, 66 of the circuit board 40. This is best shown in the cross-sectional view of FIG. 4A. Essentially, the input/output I/O contact terminal 51 is bounded on only three sides during manufacture thereof and, on its fourth side, is permitted to extend to and at the left edge 64 of the printed circuit board 40. Similarly, the chip select CS contact terminal 53 is bounded on only three sides during manufacturing thereof and, on its fourth side, extends up to and at the right edge 66 of the printed circuit board. The bounding of the end terminals on only three sides and not the fourth helps facilitate manufacturing of the subject printed circuit board 40 and thus, reduces its costs. Other desirable effects include providing a set of contacts having dissimilar sizes with the larger contact terminals being disposed at the board edges to enhance registration of the outer terminals when the circuit board is unintentionally misaligned by being rotated in the plane of the board during insertion of the cartridge into the printer. In the preferred embodiment shown, the terminals are not identically sized and are therefore better configured to ensure registration and electrical contact with the associated printer while saving costs by providing smaller sized terminals near the center of the single row of terminals 60.

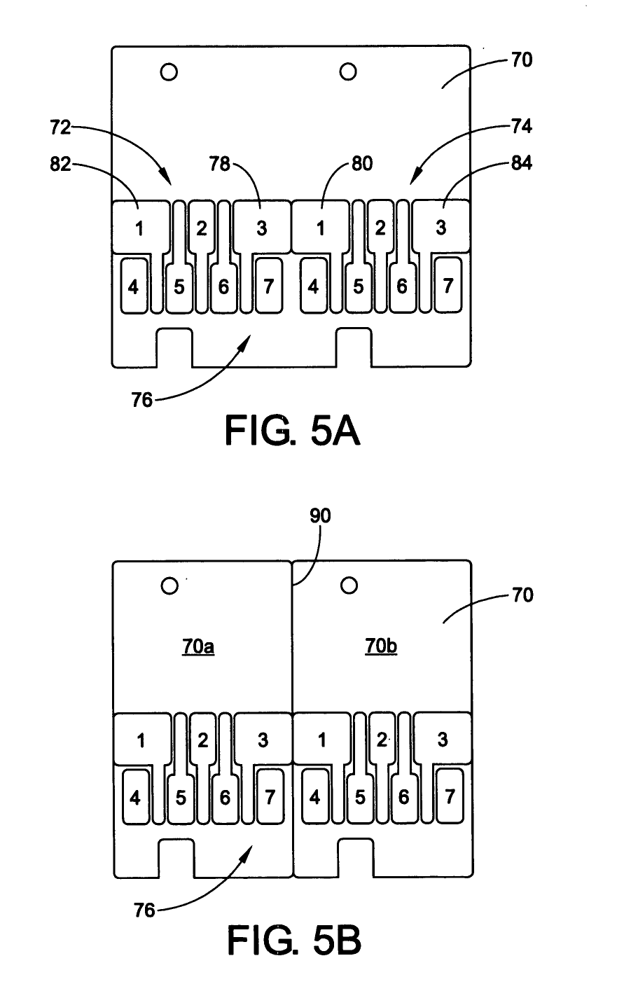

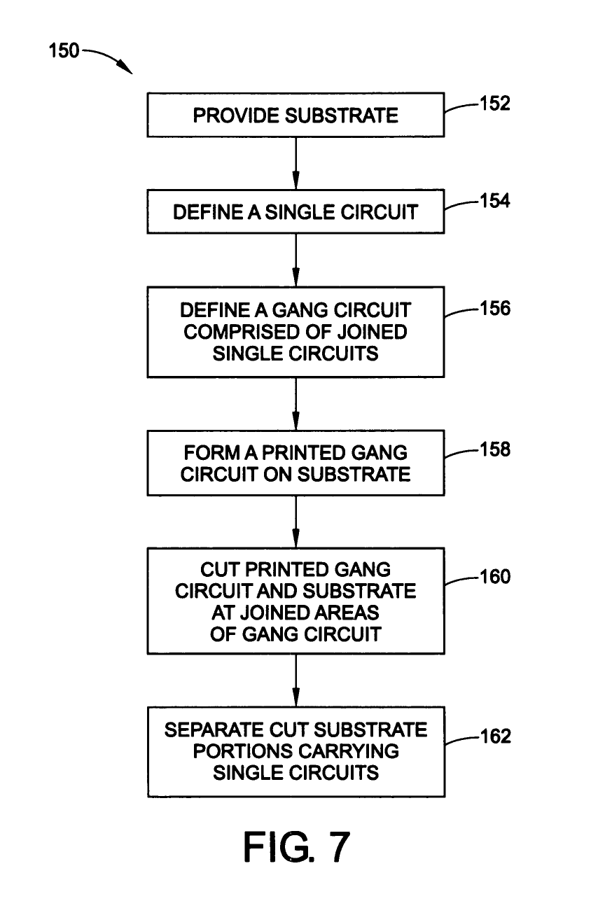

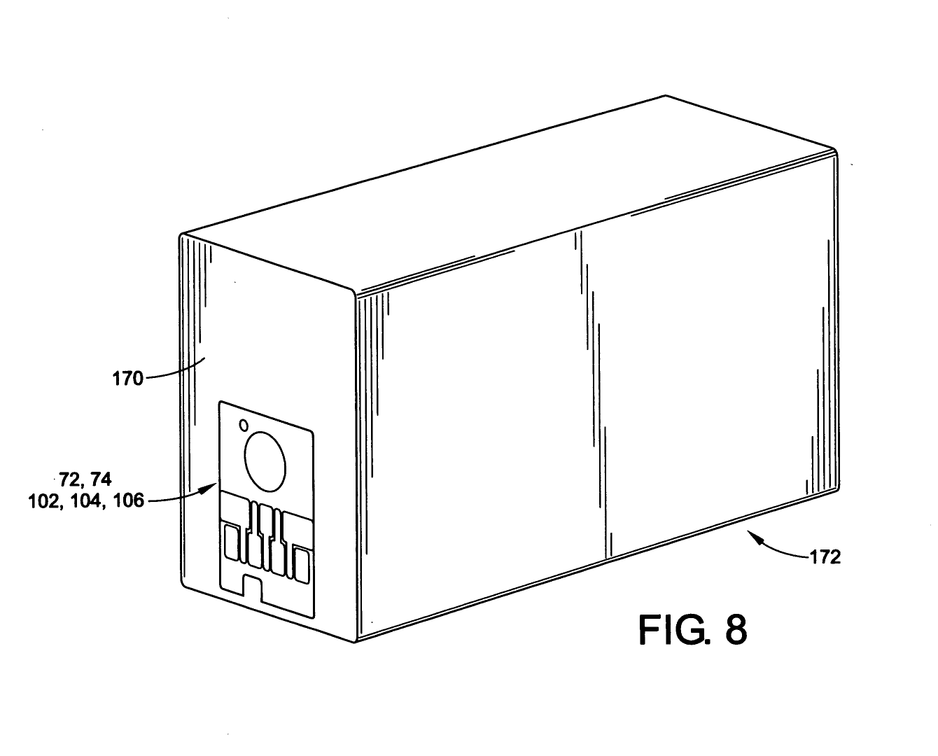

FIGS. 5A and 5B show a plurality of printed circuit boards having the novel characteristics of a plurality of terminals in a single row and being arranged on edges of the circuit board during the manufacture thereof. The preferred method of manufacture will be described in conjunction with the flowchart of FIG. 7 and with reference to FIGS. 5A and 5B. Initially, in step 152, a substrate 70 is provided. The substrate is of a typical structure as defined by industry standards and may include flexible circuits, rigid printed circuit board constructions including multiple and single layer formations or any other now known or hereinafter developed forms of circuit board. Next, in step 154, a single circuit is defined. Typically, the single circuit is defined in a “Gerber file” using apparatus and development tools well known in the art. In FIG. 5A, the substrate 70 is provided for carrying at least a first 72 and a second 74 circuit in a side by side relationship.

In the method of 150 in FIG. 7, a gang circuit 76 is defined at step 156 comprised of conjoined single circuits. The first single circuit 72 is joined at a first terminal 78 with a first terminal 80 defined by the second single circuit 74. The gang circuit 76 preferably includes two or more circuits and is shown in FIG. 5A as comprised of a first single circuit 72 and a second single circuit 74. Although only a pair of single circuits 72, 74 are illustrated in FIG. 5A, it is to be appreciated that multiple single circuits 72, 74, such as a dozen, several dozen, or more, as desired, can be formed on the substrate 70 according to the techniques described herein. More particularly, a further single circuit (not shown) can be formed to the left of the first single circuit 72 wherein a corresponding contact terminal (not shown) would be formed on the substrate 70 in a conjoined fashion with a second terminal 82 of the first circuit 72. Similarly, the gang circuit 76 can be expanded to the right using the preferred method of the application by providing a further single circuit (not shown) to the right of the second single circuit 74 with a contact terminal (not shown) joined with a second terminal 84 formed in the second single circuit 74. In step 158, the gang circuit 76 is formed on the substrate 70 in a manner as shown in FIG. 5A.

In FIG. 5B, a line 90 is defined relative to the substrate 70 and the gang circuit 76. The line essentially bisects each side of the gang circuit 76 and as well, bisects the first terminals 78, 80 of the first and second circuits 72, 74. Although only a single line is needed to bisect a pair of conjoined circuits, multiple lines are used to bisect three or more conjoined circuits.

Next, in step 160, the gang circuit 76 and the substrate 70 are cut along the line 90 resulting in multiple single circuits 72, 74 carried on separate substrate portions 70a, 70b and formed substantially as illustrated in FIGS. 4 and 4A in accordance with the preferred embodiment. In step 162, the cut substrate portions carrying the single circuits 72, 74 are separated into forms substantially as shown in FIGS. 4 and 4A. These are then mounted onto an ink or toner cartridge housing 170, such as shown in FIG. 8, in accordance with well known mounting techniques such as by gluing, staking, ultrasonic welding, or by any other means to form a consumable ink or toner cartridge 172 for use with associated ink or laser printers.

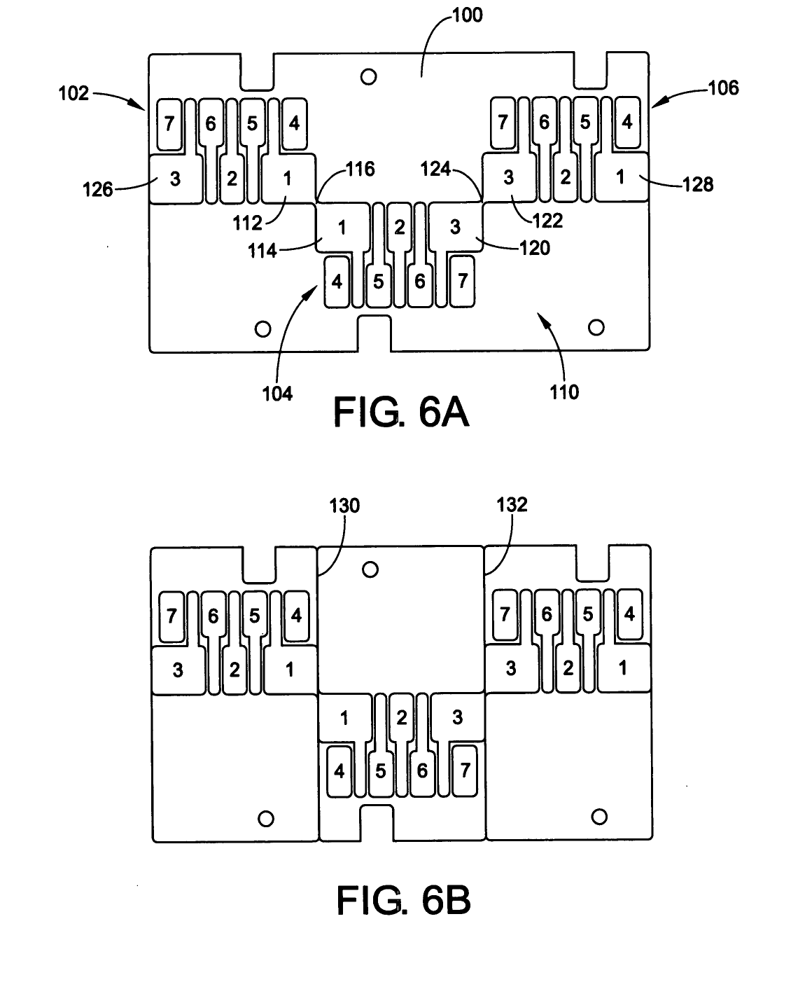

FIGS. 6A and 6B show an alternative preferred embodiment of a method for fabricating a printed circuit board in accordance with the present application. As shown there, a substrate 100 is provided defining conjoined first, second, and third single circuits 102, 104, 106. Collectively, the single circuits define a gang circuit 110. It is to be appreciated that although a set of three single circuits 102, 104, 106 are illustrated, the embodiment includes forming a plurality of single circuits on a single substrate wherein each of the single circuits are joined at selected locations. To that end, a further single circuit (not shown) can be formed to the left of the first single circuit 102 wherein a terminal (not shown) is conjoined with a second terminal 126 on the first single circuit 102. Similarly, the gang circuit 110 can be expanded to the right by adding a further single circuit (not shown) having a terminal (not shown) joined with a second terminal 128 on the third single circuit 106.

As illustrated in FIG. 6A, the gang circuit 110 is comprised of joined single circuits 102, 104, and 106. The first single circuit 102 is joined to the second single circuit 104 by a first contact terminal 112 of the first circuit 102 being joined with a first contact terminal 114 of the second single circuit 104 at an intersection junction 116. Similarly, an intersection junction 124 is provided between a second terminal 120 of the second single circuit 104 and a first terminal 122 of the third single circuit 106. Essentially, in accordance with the preferred form, the first single circuit 102 is joined with the second single circuit 104 at a junction interface 116. Similarly, the third single circuit 106 is joined with the second single circuit 104 at a junction interface 124. It is to be appreciated that although the junction interface is illustrated in FIG. 6A as being a small overlap portion between terminals on adjoining single circuits, other proportions of joined areas between adjacent circuits can be selected as needed or desired.

Next, in step 158, the gang circuit 110 is formed on the substrate 100 as illustrated in FIG. 6A such as depositing metal portions onto a substrate and etching steps according to techniques known in the art. The printed gang circuit and substrate are cut along dividing lines 130, 132 resulting in the novel circuits of the type illustrated in FIGS. 4 and 4A in accordance with the present application with terminals being arranged on the circuit board at two edges thereof. These are then mounted onto an ink or toner cartridge housing 170, such as shown in FIG. 8, in accordance with well-known mounting techniques, such as by gluing, staking, ultrasonic welding, or by any other means to form a consumable ink or toner cartridge 172 for use with associated ink or laser printers.

The exemplary embodiments have been described with reference to the preferred embodiments. Obviously, modifications and alterations will occur to others upon reading and understanding the preceding detailed description. It is intended that the exemplary embodiment be construed as including all such modifications and alterations insofar as they come within the scope of the appended claims or the equivalents thereof.

1. A circuit board for use with an associated printing device, the circuit board comprising:
a substrate;
a storage device carried on the substrate for storing data relating to marking material consumed during a printing operation;
a plurality of terminals arranged on said substrate along one axis thereof, the plurality of terminals establishing selective electrical and mechanical contact with a corresponding set of pins on the associated printing device based on relative movement between the substrate and the set of pins of the associated printing device;
a first set of said plurality of terminals arranged on said substrate being for read/write operations of said storage device to modify said data relating to the marking material;
a second set of said plurality of terminals arranged on said substrate being for communicating electrical power to said storage device; and,
at least two of said first set of said plurality of terminals being arranged on said substrate at two edges thereof.

2. The circuit board according to claim 1 wherein:
said plurality of terminals on said circuit board are arranged in a single row with said at least two of said first set of said plurality of terminals being located at the outermost ends of said row.

3. The circuit board according to claim 2 wherein said first set of said plurality of terminals includes a data I/O terminal, a power supply terminal, a chip select signal terminal, a read/write control signal terminal, and a clock signal terminal.

4. The circuit board according to claim 3 wherein said data I/O terminal and said chip select signal terminal are located at said outermost ends of said row.

5. The circuit board according to claim 4 wherein said plurality of terminals are arranged on said circuit board in said single row in order according to a first ground terminal, said data I/O terminal, said read/write control signal terminal, a power supply terminal, said clock signal terminal, said chip select signal terminal, and a second ground signal terminal, wherein said data I/O terminal and said chip select signal terminal extend in opposite directions beyond said first and second ground signal terminals, respectively, at said two edges of said circuit board.

6. A method of manufacturing a circuit board comprising:
defining a first circuit having a first terminal;
defining a second circuit having a second terminal;
providing a substrate;
forming the first and second circuits on the substrate with said first and second terminals being conjoined at a conjoined area; and,
cutting said substrate and said first and second terminal through said conjoined area to form:
i) a first circuit board of a first portion of said substrate carrying said first circuit with said first terminal extending to an edge of the first circuit board defined by said cutting; and,
ii) a second circuit board of a second portion of said substrate carrying said second circuit with said second terminal extending to an edge of the second circuit board defined by said cutting.

7. The method according to claim 6 wherein:
said providing includes providing a rigid circuit board, and;
said forming includes forming conductive traces on said substrate.

8. The method according to claim 6 wherein:
said defining said first circuit includes defining a first circuit having a plurality of first terminals arranged in a single row; and,
said defining said second circuit includes defining a second circuit having a plurality of second terminals arranged in said single row.

9. The method according to claim 6 wherein said defining said first circuit and said defining said second circuit includes defining substantially identical first and second circuits.

10. The method according to claim 6 wherein said forming said first circuit on the substrate and said forming the second circuit on the substrate includes forming the first and second circuits on the substrate in a side by side non-inverted relationship.

11. The method according to claim 6 wherein said forming said first circuit on the substrate and said forming the second circuit on the substrate includes forming the first and second circuits on the substrate in a side by side inverted relationship.

12. The method according to claim 6 wherein:
said defining said first circuit includes defining a first circuit having a first terminal bounded on three sides and unbounded on a fourth side; and,
said defining said second circuit includes defining a second circuit having a second terminal bounded on three sides and unbounded on a fourth side.

13. The method according to claim 12 wherein:
said forming said first and second circuits on said substrate includes forming said first and second circuits on said substrate with said first and second terminals being conjoined at said unbounded fourth side thereof in said conjoined area.

14. A cartridge for use with an associated marking device consuming marking material, the cartridge comprising:
a housing defining a chamber configured to hold quantity of an associated marking material;
an outlet port for communicating said associated marking material from the chamber of the housing to the associated marking device; and,
a circuit board carried relative to said housing, the circuit board including:
a substrate;
a storage device carried on the substrate for storing data relating to the associated marking material consumed by the associated marking device;
a plurality of terminals arranged on said substrate along one axis thereof, the plurality of terminals establishing selective electrical and mechanical contact with a corresponding set of pins on the associated printing device based on relative movement between the substrate and the set of pins of the associated printing device;
a first set of said plurality of terminals arranged on said substrate being for read/write operations of said storage device to modify said data relating to the marking material;
a second set of said plurality of terminals arranged on said substrate being for communicating electrical power to said storage device; and,
at least two of said first set of said plurality of terminals being arranged on said circuit board at two edges thereof.

15. The cartridge according to claim 14 wherein:
said plurality of terminals on said circuit board are arranged in a single row with said at least two of said first set of said plurality of terminals being located at the outermost ends of said row.

16. The cartridge according to claim 15 wherein said first set of said plurality of terminals includes a data I/O terminal, a power supply terminal, a chip select signal terminal, a read/write control signal terminal, and a clock signal terminal.

17. The cartridge according to claim 16 wherein said data I/O terminal and said chip select signal terminal are located at said outermost ends of said row.

18. The cartridge according to claim 17 wherein said plurality of terminals are arranged on said circuit board in said single row in order according to a first ground terminal, said data I/O terminal, said read/write control signal terminal, a power supply terminal, said clock signal terminal, said chip select signal terminal, and a second ground signal terminal, wherein said data I/O terminal and said chip select signal terminal extend beyond said first and second ground signal terminals, respectively, at said two edges of said circuit board.

19. The cartridge according to claim 18 wherein the chamber defined by said housing is adapted to hold ink.

20. The cartridge according to claim 18 wherein the chamber defined by said housing is adapted to hold toner.

21. A method of manufacturing an apparatus for use with an associated marking device consuming marking material, the method comprising:
providing a circuit board having:
a storage device for storing data relating to marking material;
a plurality of terminals thereon arranged on said circuit board along one axis thereof;
a first set of said plurality of terminals arranged on said circuit board and being for read/write operations of said storage device to modify said data relating to the marking material;
a second set of said plurality of terminals arranged on said circuit board and being for communicating electrical power to said storage device; and,
at least two of said first set of said plurality of terminals being disposed on said circuit board at two edges thereof; providing a cartridge including:
a housing defining a chamber configured to hold quantity of the marking material; and,
an outlet port for communicating the marking material from the chamber of the housing to the associated marking device; and,
mounting the circuit board in a position relative to the cartridge.

22. The method according to claim 21 wherein the providing said circuit board includes arranging said plurality of terminals on said circuit board in a single row with said at least two of said first set of said plurality of terminals being located at the outermost ends of said row.

23. The method according to claim 22 wherein the providing said circuit board includes providing, as said first set of said plurality of terminals, a data I/O terminal, a power supply terminal, a chip select signal terminal, a read/write control signal terminal, and a clock signal terminal.

24. The method according to claim 23 wherein the providing said circuit board includes disposing said data I/O terminal and said chip select signal terminals at said outermost ends of said row.

25. The method according to claim 24 wherein the providing said circuit board includes arranging said plurality of terminals on said circuit board in said single row in order according to a first ground terminal, said data I/O terminal, said read/write control signal terminal, a power supply terminal, said clock signal terminal, said chip select signal terminal, and a second ground signal terminal, wherein said data I/O terminal and said chip select signal terminal extend in opposite directions beyond said first and second ground signal terminals, respectively, at said two edges of said circuit board.

26. The method according to claim 21 wherein the providing said circuit board includes:
defining a first circuit having a first terminal;
defining a second circuit having a second terminal;
providing a substrate;
forming the first and second circuits on the substrate with said first and second terminals being conjoined at a conjoined area; and,
cutting said substrate and said first and second terminal through said conjoined area to form:
i) a first circuit board of a first portion of said substrate carrying said first circuit with said first terminal extending to an edge of the first circuit board defined by said cutting; and,
ii) a second circuit board of a second portion of said substrate carrying said second circuit with said second terminal extending to an edge of the second circuit board defined by said cutting.

27. The method according to claim 26 wherein the providing said circuit board includes providing a rigid circuit board.

28. The method according to claim 26 wherein the providing said circuit board includes:
defining a first circuit having a plurality of first terminals arranged in a single row; and,
defining a second circuit having a plurality of second terminals arranged in a single row.

29. The method according to claim 26 wherein the providing said circuit board includes defining substantially identical first and second circuits.

30. The method according to claim 26 wherein the providing said circuit board includes forming said first circuit on the substrate and said forming the second circuit on the substrate includes forming the first and second circuits on the substrate in a side by side non-inverted relationship.

31. The method according to claim 26 wherein the providing said circuit board includes forming said first circuit on the substrate and said forming the second circuit on the substrate includes forming the first and second circuits on the substrate in a side by side inverted relationship.

32. The method according to claim 26 wherein the providing said circuit board includes:
defining a first circuit having a first terminal bounded on three sides and unbounded on a fourth side; and,
defining a second circuit having a second terminal bounded on three sides and unbounded on a fourth side.

33. The method according to claim 32 wherein the providing said circuit board includes forming said first and second circuits on said substrate with said first and second terminals being conjoined at said unbounded fourth side thereof in said conjoined area.
